(19) United States
(12) Patent Application Publication
(10) Pub. No.: US 2014/0264693 A1
(43) Pub. Date: Sep. 18, 2014

(54) Cover-Free Sensor Module And Method Of Making Same

(71) Applicant: Optiz, Inc., Palo Alto, CA (US)

(72) Inventors: Vage Oganesian, Sunnyvale, CA (US); Zhenhua Lu, East Palo Alto, CA (US)

(73) Assignee: Optiz, Inc., Palo Alto, CA (US)

(21) Appl. No.: 14/201,154

(22) Filed: Mar. 7, 2014

Related U.S. Application Data
(60) Provisional application No. 61/778,244, filed on Mar. 12, 2013.

(51) Int. Cl. H01L 23/538; H01L 23/00; H01L 31/02

(52) U.S. Cl. CPC H01L 23/5386; H01L 31/02019; H01L 24/95
USPC 257/432; 257/448; 257/414; 438/125; 438/65; 438/49

(57) ABSTRACT

A sensor package includes host substrate assembly includes a first substrate, circuit layers in the first substrate, and first contact pads electrically coupled to the circuit layers. A sensor chip includes a second substrate with opposing first and second surfaces, sensor(s) formed on or under the first surface of the second substrate, a plurality of second contact pads formed at the first surface of the second substrate and which are electrically coupled to the sensor(s), a plurality of holes each formed into the second surface of the second substrate and extends through the second substrate to one of the second contact pads, and conductive leads each extending from one of the second contact pads, through one of the plurality of holes, and along the second surface of the second substrate. A plurality of electrical connectors each electrically connect one of the first contact pads and one of the conductive leads.

### RELATED APPLICATIONS

This application claims the benefit of U.S. Provisional Application No. 61/778,244, filed Mar. 12, 2013, and which is incorporated herein by reference.

### FIELD OF THE INVENTION

The present invention relates to packaging of microelectronic devices, and more particularly to a packaging of optical or chemical semiconductor devices.

### BACKGROUND OF THE INVENTION

The trend for semiconductor devices is smaller integrated circuit (IC) devices (also referred to as chips), packaged in smaller packages (which protect the chip while providing off chip signaling connectivity). One example are image sensors, which are IC devices that include photo-detectors which transform incident light into electrical signals (that accurately reflect the intensity and color information of the incident light with good spatial resolution).

There are different driving forces behind the development of wafer level packaging solutions for image sensors. For example, reduced form factor (i.e. increased density for achieving the highest capacity/volume ratio) overcomes space limitations and enables smaller camera module solutions. Increased electrical performance can be achieved with shorter interconnect lengths, which improves electrical performance and thus device speed, and which strongly reduces chip power consumption.

Presently, chip-on-board (COB—where the bare chip is mounted directly on a printed circuit board) and Shellcase Wafer Level CSP (where the wafer is laminated between two sheets of glass) are the dominant packaging and assembly processes used to build image sensor modules (e.g. for mobile device cameras, optical mice, etc.). However, as higher resolution pixel image sensors are used, COB and Shellcase WLCSP assembly becomes increasingly difficult due to assembly limitations, size limitations (the demand is for lower profile devices), yield problems and required improvement in optical performance.

There is a need for an improved package and packaging technique that provides a low profile packaging solution with improved performance.

### BRIEF SUMMARY OF THE INVENTION

A sensor package includes a host substrate assembly and a sensor chip. The host substrate assembly includes a first substrate, one or more circuit layers in the first substrate, and a plurality of first contact pads electrically coupled to the one or more circuit layers. The sensor chip includes a second substrate with opposing first and second surfaces, one or more sensors formed on or under the first surface of the second substrate, a plurality of second contact pads formed at the first surface of the second substrate and which are electrically coupled to the one or more sensors, a plurality of holes each formed into the second surface of the second substrate and extends through the second substrate to one of the second contact pads, and conductive leads each extending from one of the second contact pads, through one of the plurality of holes, and along the second surface of the second substrate. A plurality of electrical connectors each electrically connect one of the first contact pads and one of the conductive leads.

A method of forming a sensor package includes providing a first substrate that includes one or more circuit layers and a plurality of first contact pads electrically coupled to the one or more circuit layers, providing a sensor chip that includes a second substrate with opposing first and second surfaces, one or more sensors on or under the first surface of the second substrate, and a plurality of second contact pads formed at the first surface of the second substrate and which are electrically coupled to the one or more sensors, forming a plurality of holes into the second surface of the second substrate, wherein each of the plurality of holes extends through the second substrate and to one of the second contact pads, forming a plurality of conductive leads each extending from one of the second contact pads, through one of the plurality of holes, and along the second surface of the second substrate, and forming a plurality of electrical connectors each electrically connecting one of the first contact pads and one of the conductive leads.

Other objects and features of the present invention will become apparent by a review of the specification, claims and appended figures.

### BRIEF DESCRIPTION OF THE DRAWINGS

FIGS. 1A-1H are cross sectional side views showing in sequence the steps in forming the sensor assembly.

FIG. 2 is a cross sectional side view showing an alternate embodiment of the sensor assembly.

FIGS. 3A-3D are top views showing different configurations of the openings in the spacer substrate.

### DETAILED DESCRIPTION OF THE INVENTION

The present invention relates to sensor devices, and more particularly to the forming a cover-free chip scale package. The active area of the sensor can be exposed to the environment for detecting physical substances such as gases and chemicals, or can be integrated inside a lens module structure where only photons are detected without the distortion or photon loss associated with a protective cover.

FIGS. 1A-1H illustrate the formation of a packaged image sensor, although the invention is not limited to image sensors. The formation begins with a wafer 10 (substrate) containing multiple image sensors 12 formed thereon, as illustrated in FIG. 1A. Each image sensor 12 includes an active area with a plurality of photo detectors 14, as well as supporting circuitry 16 and contact pads 18. The contact pads 18 are electrically connected to the photo detectors 14 and/or their supporting circuitry 16 for providing off chip signaling. Each photo detector 14 converts light energy to a voltage signal. Additional circuitry may be included to amplify the voltage, and/or convert it to digital data. Color filters and/or microlenses 20 can be mounted over the photo detectors 14. Sensors of this type are well known in the art, and not further described herein.

A protector assembly 21 is formed by starting with a spacer substrate 22, which can be glass or any other rigid material. Glass is the preferred material for spacer substrate 22. Glass thickness in range of 25 to 1500 μm is preferred. Sensor area window openings 24 are formed in the spacer substrate 22 at locations that will correspond to (i.e. be disposed over) the active areas of sensors 12. Openings 24 can be formed by laser, sandblasting, etching or any other appropriate cavity forming methods. An optional layer of spacer material 26 can be deposited on spacer substrate 22. This deposition can occur before the formation of openings 24, so that corresponding openings are formed in the spacer layer 26 as well. However, the dimensions of openings 24 in spacer material 26 can be different from those in spacer substrate 22 (e.g. the dimensions of openings 24 in spacer material 26 can be larger or smaller than those in substrate 22). The spacer layer material 26 can be polymer, epoxy or any other appropriate materials, which is deposited by roller, spray coating, screen printing or any other appropriate methods. A thickness in the range of 5 to 500 μm is preferred for the spacer layer 26. A protective tape or similar layer 28 is placed/mounted over the spacer substrate 22, which forms cavities 30 at the openings 24 in substrate 22 and material 26. The height of cavities 30 is preferably in the range of 5 to 500 μm. The resulting structure of protector assembly 21 is shown in FIG. 1B.

The protective structure assembly 21 is mounted/bonded to the active side of substrate 10 by a bonding material. For example, epoxy can be deposited by roller and then heat cured, or any other appropriate bonding methods can be used. The protective structure assembly 21 separately encapsulates the active area for each sensor 12, but cavities 30 preferably do not extend to contact pads 18. Silicon thinning is then performed to reduce the thickness of substrate 10. Silicon thinning can be done by mechanical grinding, chemical mechanical polishing (CMP), wet etching, atmospheric downstream plasma (ADP), dry chemical etching (DCE), a combination of aforementioned processes or any another appropriate silicon thinning method(s). The thickness of the thinned silicon is preferably in range of 100 to 2000 μm. The resulting structure is shown in FIG. 1C.

Holes 32 are then formed into the bottom surface of substrate 10, and extend through substrate 10 to expose contact pads 18 (where spacer material 26 provides mechanical support for contact pads 18 during the hole forming process). Holes 32 can be made by laser, dry etch, wet etch or any another appropriate hole forming method(s) that are well known in the art. Preferably, a laser is used to form holes 32. Preferably the width of the holes 32 at contact pad 18 are no larger than contact pad 18 so that there is no exposed silicon around contact pad 18. The opening of the holes 32 at the bottom surface of substrate 10 is preferably larger than the width thereof at contact pads 18, whereby holes 32 have a funnel shape that ends at and exposes contact pads 18. Alternately, holes 32 can have vertical sidewalls. An insulation layer 34 is then formed along the sidewalls of holes 32 and the bottom surface of substrate 10 (but not over contact pads 18). Layer 34 can be formed by depositing a layer of insulation material such as silicon dioxide or silicon nitride over the non-active side of substrate 10. A non-limiting example can include silicon dioxide with a thickness of at least 0.5 μm by PECVD or any another appropriate deposition method(s). A photolithography process is used to remove the portions of layer 34 over contact pads 18 in holes 32. Specifically, a layer of photoresist is deposited over the non-active side of the wafer by spray coating or any another appropriate deposition method(s). The photoresist is exposed and etched using appropriate photolithography processes that are well known in the art to remove the photoresist over contact pads 18. The exposed portions of insulation layer 34 over the contact pads 18 can then be selectively removed by, for example, plasma etching. The photoresist can then be removed by dry plasma etching or any other chemical/wet photoresist stripping method that are well known in the art. The resulting structure is shown in FIG. 1D.

A layer of electrically conductive material is deposited over the insulation layer 34. The electrically conductive material can be copper, aluminum, conductive polymer or any other appropriate electric conductive material(s). The electrically conductive material can be deposited by physical vapor deposition (PVD), chemical vapor deposition (CVD), plating or any other appropriate deposition method(s). Preferably, the electrically conductive material layer is a first layer of titanium and a second layer of copper, deposited by physical vapor deposition (PVD). The conductive layer is then patterned by a photolithography process (i.e. photoresist 36 is deposited over the conductive layer and is exposed and selectively etched to remain only in holes 32 and selected portions adjacent holes 32, followed by a conductive material etch to remove exposed portions of conductive e layer). What remains are electrical traces 38 of the conductive material each extending from one of the contact pads 18, along the sidewall of the hole in which the contact pad sits, and over the bottom surface of the substrate 10, as illustrated in FIG. 1E.

The photoresist 36 can be stripped using dry plasma etching or any other chemical/wet photoresist stripping method that are well known in the art. Optionally, a plating process can be performed on the leads 38 (e.g Ni/Pd/Au). An optional encapsulant layer 40 can be formed over the bottom surface of substrate 10 and in holes 32 (which covers leads 38). The encapsulant layer 40 can be polyimide, ceramics, polymer, polymer composite, parylene, silicon dioxide, epoxy, silicone, porcelain, glass, resin, and a combination of aforementioned materials or any other appropriate dielectric material(s). Encapsulant layer 40 is preferably 1 to 3 μm in thickness, and the preferred material is liquid photoimagable polymer such as solder mask which can be deposited by spray coating. Optionally, the holes 32 can be filled by the encapsulation material. The encapsulant layer 40 is then patterned using a photolithography process to selectively remove portions of layer 40 to define contact pads 42 (i.e. exposed portions of leads 38). The resulting structure is shown in FIG. 1F.

Interconnects 44 are next formed on contact pads 42. Interconnects 44 can be ball grid array (BGA), land grid array (LGA), conductive bumping, copper pillar or any other appropriate interconnect structure. Ball grid array is one of the preferred methods of interconnection, and interconnects 44 can be deposited by screen printing followed by a reflow process. The structure is then diced/singulated to form separate die each with one of the sensors 12. Wafer level dicing/singulation of components can be done with mechanical blade dicing equipment, laser cutting or any other appropriate processes. The resulting structure is shown in FIG. 1G.

The structure in FIG. 1G can be mounted to a host substrate 46 using interconnects 44. Host substrate 46 can be an organic flex PCB, FR4 PCB, silicon (rigid), glass, ceramic or any other type of substrate that is applicable. The host substrate 46 includes contact pads 48 electrically connected to circuitry layer(s) 50. Each interconnect 44 electrically connects one of the contact pads 42 with one of the contact pads 48 using surface mounting technologies (SMT) that are well known in the art (which can include pick and place devices). The protective tape 28 is then removed. A lens module 22 may be mounted to host substrate 46 (i.e. over the sensor 12), with the resulting structure illustrated in FIG. 1H. An exemplary lens module 52 can include a housing 54 bonded to the host substrate 46, where the housing 54 supports one or more lenses 56 over the sensor 12. With this final structure, the image sensor 12 is secured to host substrate 46 by interconnects 44, and lens module 52 is also secured to the host substrate 46, where the lens module 52 focuses incoming light onto photo detectors 14 directly without any intervening protective substrates or other optical mediums that can distort the light or cause photon loss. The lens module 52 protects image sensor 12 from contamination. Conductive leads 38 electrically connect contact pads 18 to interconnects 44, which in turn are electrically connected to contact pads 48 and circuit layers 50 of host substrate 46.

The above described packaging technique for sensor 12 is suitable for non-optical applications as well. For example, sensor 12 can include a chemical detector 60 instead of photo detectors 14, as illustrated in FIG. 2. In this case, no lens module 52 is included, and the sensor 12 is exposed to the environment for detecting physical substances such as gases or chemicals.

It should be noted that opening 24 in spacer substrate 22 over the active area of sensor 12 need not share the same shape and/or dimensions. FIGS. 3A-3D illustrate exemplary configurations of opening 24 in spacer substrate 22 relative to the active area 12a (i.e. that area of substrate 10 containing one or more sensors) of sensor 12 underneath substrate 22. As illustrated in FIG. 3A, a single opening 24 has dimensions substantially matching those of the active area 12a underneath. FIG. 3B illustrates a single opening 24 having dimensions that are smaller than those of the active area 12a. FIGS. 3C and 3D illustrate that opening 24 can be a plurality of rectangular or circularly openings disposed over active area 12a.

It is to be understood that the present invention is not limited to the embodiment(s) described above and illustrated herein, but encompasses any and all variations falling within the scope of the appended claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Further, as is apparent from the claims and specification, not all method steps need be performed in the exact order illustrated or claimed, but rather in any order that allows the proper formation of the packaged sensor. Lastly, single layers of material could be formed as multiple layers of such or similar materials, and vice versa.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements therebetween.

1. A sensor package, comprising:
a host substrate assembly including:
a first substrate,
one or more circuit layers in the first substrate,
a plurality of first contact pads electrically coupled to the one or more circuit layers;
a sensor chip that includes:
a second substrate with opposing first and second surfaces,
one or more sensors formed on or under the first surface of the second substrate,
a plurality of second contact pads formed at the first surface of the second substrate and which are electrically coupled to the one or more sensors,
a plurality of holes each formed into the second surface of the second substrate and extends through the second substrate to one of the second contact pads, and
conductive leads each extending from one of the second contact pads, through one of the plurality of holes, and along the second surface of the second substrate;
a plurality of electrical connectors each electrically connecting one of the first contact pads and one of the conductive leads.

2. The sensor package of claim 1, further comprising:
a spacer substrate mounted over the first surface of the second substrate, wherein the spacer substrate includes one or more openings that are disposed over the one or more sensors.

3. The sensor package of claim 2, further comprising:
spacer material disposed between the spacer substrate and the second substrate, wherein the spacer material includes one or more openings that are disposed over the one or more sensors, and wherein the spacer material is disposed on and provides mechanical support to the second contact pads.

4. The sensor package of claim 1, further comprising:
a spacer substrate mounted on the first surface of the second substrate, wherein the spacer substrate includes one or more openings that are disposed over the one or more sensors, and wherein the spacer substrate is disposed on and provides mechanical support to the second contact pads.

5. The sensor package of claim 1, further comprising:
a layer of insulation material between each of the conductive leads and the second substrate.

6. The sensor package of claim 1, further comprising:
a layer of insulation material disposed over the second surface of the second substrate and covering the conductive leads except for contact pad portions thereof which are in electrical contact with the plurality of electrical connectors.

7. The sensor package of claim 1, wherein each of the plurality of holes has a funnel shaped cross section.

8. The sensor package of claim 1, wherein the one or more sensors includes a plurality of photo detectors configured to receive light incident on the first surface of the second substrate.

9. The sensor package of claim 8, further comprising:
a lens module mounted to the host substrate assembly, wherein the lens module includes one or more lenses disposed for focusing light onto the photo detectors.

10. The sensor package of claim 1, wherein the one or more sensors includes a chemical detector configured to detect physical substances in proximity of the first surface of the second substrate.

11. A method of forming a sensor package, comprising:
providing a first substrate that includes one or more circuit layers and a plurality of first contact pads electrically coupled to the one or more circuit layers;
providing a sensor chip that includes a second substrate with opposing first and second surfaces, one or more sensors on or under the first surface of the second substrate, and a plurality of second contact pads formed at the first surface of the second substrate and which are electrically coupled to the one or more sensors;
forming a plurality of holes into the second surface of the second substrate, wherein each of the plurality of holes extends through the second substrate and to one of the second contact pads;
forming a plurality of conductive leads each extending from one of the second contact pads, through one of the plurality of holes, and along the second surface of the second substrate;
forming a plurality of electrical connectors each electrically connecting one of the first contact pads and one of the conductive leads.

12. The method of claim 11, further comprising:
mounting a spacer substrate over the first surface of the second substrate, wherein the spacer substrate includes one or more openings that are disposed over the one or more sensors.

13. The method of claim 12, further comprising:
forming spacer material between the spacer substrate and the second substrate, wherein the spacer material includes one or more openings that are disposed over the one or more sensors, wherein the spacer material is disposed on and provides mechanical support to the second contact pads during the forming of the plurality of holes.

14. The method of claim 11, further comprising:
mounting a spacer substrate over the first surface of the second substrate, wherein the spacer substrate includes one or more openings that are disposed over the one or more sensors, wherein the spacer substrate is disposed on and provides mechanical support to the second contact pads during the forming of the plurality of holes.

15. The method of claim 11, further comprising:
forming a layer of insulation material between each of the conductive leads and the second substrate.

16. The method of claim 11, further comprising:
forming a layer of insulation material disposed over the second surface of the second substrate and covering the conductive leads except for contact pad portions thereof which are in electrical contact with the plurality of electrical connectors.

17. The method of claim 11, wherein each of the plurality of holes has a funnel shaped cross section.

18. The method of claim 11, wherein the one or more sensors includes a plurality of photo detectors configured to receive light incident on the first surface of the second substrate.

19. The method of claim 18, further comprising:
mounting a lens module to the first substrate, wherein the lens module includes one or more lenses disposed for focusing light onto the photo detectors.

20. The method of claim 11, wherein the one or more sensors includes a chemical detector configured to detect physical substances in proximity of the first surface of the second substrate.
